(19) United States
(12) Patent Application Publication
(10) Pub. No.: US 2018/0220546 A1
(43) Pub. Date: Aug. 2, 2018

(54) MODULAR EQUIPMENT CHASSIS

(71) Applicants: Bruce Meldrum, Berkshire (GB); Mark Armon, Brewster, NY (US); Carl Hicks, Wiltshire (GB)

(72) Inventors: Bruce Meldrum, Berkshire (GB); Mark Armon, Brewster, NY (US); Carl Hicks, Wiltshire (GB)

(21) Appl. No.: 15/420,850

(22) Filed: Jan. 31, 2017

(51) Int. Cl. H05K 7/14; H02B 1/34; H02B 1/052

(52) U.S. Cl. CPC H05K 7/1492; H02B 1/052; H02B 1/34

(57) ABSTRACT

A modular equipment chassis for an electronic equipment rack is disclosed. The modular equipment chassis can include a first top support, a first bottom support, a first side member, a second side member, and a first guide rail. The first side member can be coupled to a first end of each of the first top support and the first bottom support. The second side member can be coupled to an opposite second end of each of the first top support and the first bottom support. The first guide rail can be coupled with at least one of the first top support and the first bottom support at one or more of the mount locations, and the first guide rail can be configured to receive and retain at least a portion of a first electronic appliance mount.

### BACKGROUND

Electronic appliances such as audio/visual equipment, computers, power supplies, or the like, can be permanently or temporarily installed at a particular location to provide services or entertainment. In some examples, such services or entertainment can be provided by multiple different electronic appliances and distributed over a large physical area. In other examples, electronic appliances are installed proximate to a location where services or entertainment are provided.

Some electronic appliances can be rack-mounted. A rack-mounted audio/visual (A/V) system may include many small enclosed electronic appliances, but the arrangement may be disorderly and may result in an inefficient use of rack space. U.S. Pat. No. 8,582,302, titled “Modular Equipment Rack System for Data. Center”, refers to a system with upper and lower tracks with a vertical support. U.S. Patent Application Publication No. 2008/0037203, titled “System for Mounting Modules in a Rack Mounted Chassis”, refers to a system that includes sur-modules that can be secured to a chassis. U.S. Patent Application Publication No. 2012/0024803, titled “Shelf Unit for Use in a Communication Network”, refers to a kit for providing front-access cable terminations for a rear-access shelf unit mounted in a rack system.

### OVERVIEW

The present inventors have recognized, among other things, that a problem to be solved can include organizing, powering, and routing signals to or from various electronic appliances. The present subject matter can help provide a solution to this problem, such as by providing a modular equipment chassis. In an example, a venue (such as a casino, stadium, outdoor arena, etc.) occupies a large area and serves a large number of patrons. The venue can use multiple electronic appliances (e.g., audio/visual equipment, such as video displays or audio loudspeaker systems) to provide its patrons with services (e.g., maps, directories, event information, or the like) or entertainment (e.g., sporting events, television shows, music, movies, or the like). As the number of electronic appliances used increases, it can become difficult to organize, power, and route signals to or from such appliances.

In an example, a venue uses audio and video distribution services to supply a plurality (e.g., a pair, dozens, hundreds, or thousands) of audio and visual signals to one or more remote devices located remotely from a signal source. For example, centralized A/V services can be configured to deliver signals to particular rooms within a hotel (e.g., to one or more of a television, projector, monitor, speakers, or the like). Each room can separately use one or more dedicated electronic appliances to supply signals to that particular room. Some venues can have dozens or hundreds of rooms that necessitate corresponding dozens or hundreds of electronic appliances to achieve the venue's A/V distribution objectives.

In an example, electronic appliances can be installed within a server rack. Each of the electronic appliances can require its own power supply or other electrical connections to supply signals (e.g., audio/visual information) to or from the electronic appliances. As a number of electronic appliances in a particular server rack increases, or as one or more functions of an electronic appliance changes (e.g., in terms of power requirements, input or output port access, etc.), organizing the electronic appliances, supplying power to the electronic appliances, and routing signals to and from the electronic appliances becomes challenging.

Organizing, powering, and routing signals to and from the electronic appliances can be challenging when there is limited space within a server rack. Another challenge can include a lack of mounting locations to affix an electronic appliance to the server rack. Yet another challenge is that each electronic appliance can have its own unique power requirements and/or a dedicated power supply that can further limit space available within the server rack. Another challenge can be dissipating or otherwise absorbing heat generated by multiple electronic appliances (and their respective power supplies) when such appliances are mounted within a server rack and in close proximity to one another. Elevated temperatures can, in some instances, damage or compromise proper function of an electronic appliance.

The aforementioned challenges and problems can be resolved by a modular equipment chassis. In an example, the modular equipment chassis includes a first top support, a first bottom support, a first side member, a second side member, and a first guide rail. The first top support and the first bottom support can each include a plurality of corresponding mount locations, and the mount locations can be distributed across all or a portion of the first top and/or first bottom supports. The first side member can be coupled to a first end of each of the first top support and the first bottom support. The second side member can be coupled to an opposite second end of each of the first top support and the first bottom support, and, in an example, each of the first and second side members can have a height corresponding to a specified rack height.

The first guide rail can be coupled with at least one of the first top support and the first bottom support at one or more of the mount locations. The first guide rail can be configured to receive and retain at least a portion of a first electronic appliance mount. In an example, the modular equipment chassis includes the first electronic appliance mount coupled with the first guide rail. One or more enclosed electronic appliances can be coupled to the first electronic appliance mount. The modular equipment chassis can help organize electronic appliances by providing structures for mounting such electronic appliances. The modular equipment chassis can help increase a density of, or number of, electronic appliances housed within a server rack, such as by improving the organization of enclosed electronic appliances within the server rack. The modular equipment chassis can allow for a single power supply module to power numerous electronic appliances, thereby removing a need for separate power supplies for each of the electronic appliances. The consolidation of powers supplies can further increase the density of, or number of, electronic appliances within a server rack. The modular equipment chassis can improve heat dissipation within a server rack, such as by mounting the electronic appliances vertically and providing a fan assembly configured to direct cooling air about the appliances. In an example, cooling efficiency is improved because the enclosed electronic appliances will be organized and the organization can help reduce impediments to air flow within the modular equipment chassis. The use of a fan assembly can increase the air flow through the server rack.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of an example of a modular equipment chassis.

FIG. 2 is a perspective view of an example of a support for a modular equipment chassis.

FIG. 3 is a side view of a first end of the support of FIG. 2.

FIG. 4 is a perspective view of an example of a guide rail.

FIG. 5 is a side view of the guide rail of FIG. 4 with tabs facing upward.

FIG. 6 is a perspective view of a portion of a modular equipment chassis with first and second guide rails installed therein.

FIG. 7 is a perspective view of an example of an electronic appliance mount.

FIG. 8 is a perspective view of an example of a power supply module.

FIG. 9 is a perspective view of an example of a power regulator.

FIG. 10 is a schematic diagram of multiple power regulators coupled to a power supply within a modular equipment chassis.

FIG. 11 is a perspective view of an example of a power supply module, a power regulator, and an electronic appliance mount in a modular equipment chassis.

FIG. 12 is a perspective view of an example of a modular equipment chassis with a cooling fan assembly installed.

### DETAILED DESCRIPTION

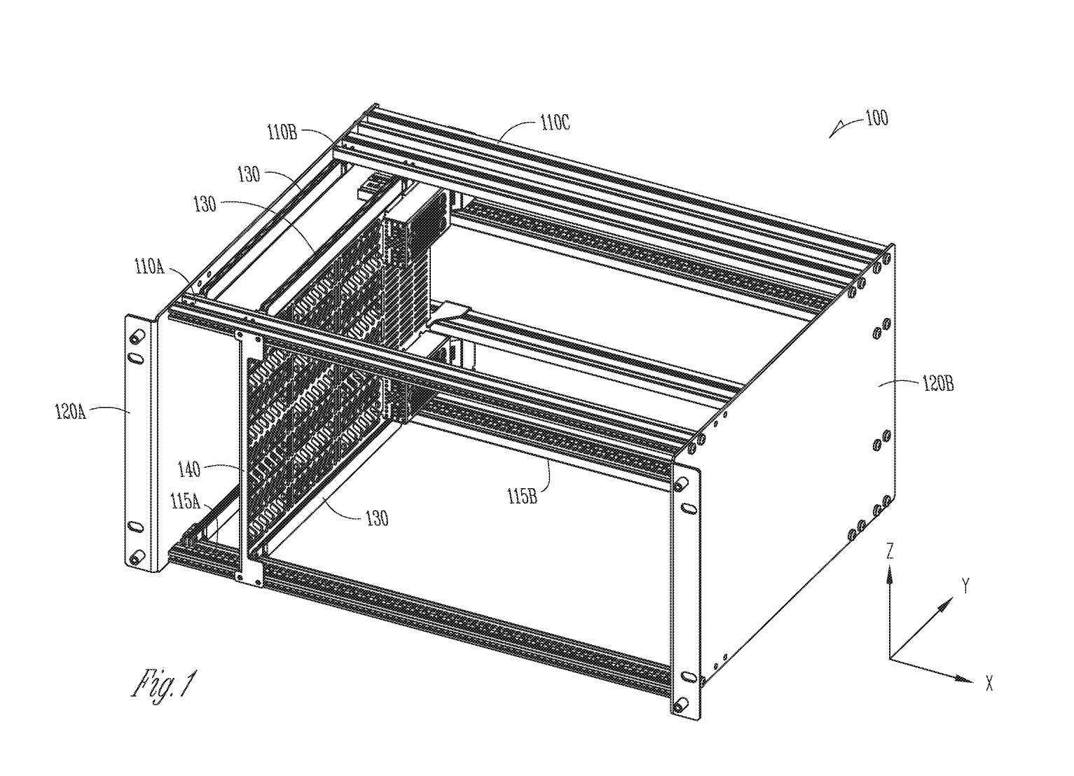

FIG. 1 is a perspective view of an example of a modular equipment chassis 100. The modular equipment chassis 100 can be configured to retain one or more electronic appliances and can help organize and/or provide power to one or more electronic appliances mounted in the modular equipment chassis 100. The modular equipment chassis 100 can be installed in an electronic equipment rack. The electronic equipment rack can have specified rack dimensions, such as can correspond to a 19 inch (or 48.26 centimeter) rack, such as provided by Electronic Industries Alliance standard EIA-310-D or Consumer Electronics Association standard CEA-310-D. In an example, the specified rack dimensions correspond to a 23 inch (or 58.42 centimeter) rack. Other specified rack dimensions can similarly be used.

The modular equipment chassis 100 can include one or more top supports and one or more bottom supports. In one example, the modular equipment chassis 100 includes a first top support 110A, a second top support 110B, a third top support 110C, a first bottom support 115A, a second top support 115B, a third top support (not shown, obscured by the first top support 110A), a first side plate 120A, a second side plate 120B, one or more guide rails 130, and one or more electronic appliance mounts 140. In an example, the first, second and third top supports 110A, 110B, and 110C are include in one or more top supports. In an example, the first bottom support 115A, the second bottom support 115B, and the third bottom support are included in one or more bottom supports. In an example, the first and second side plates 120A. and 120B are respectively coupled to, and extend between (e.g., in the direction of the X axis indicated by the coordinates shown in FIG. 1), opposite sides of the one or more top supports 110A, 110B, and 1100 and one or more bottom supports 115A, 115B. In some examples, the first and second side plates 120A and 120B have a height (e.g., in the direction of the Z axis indicated by the coordinates shown in FIG. 1) corresponding to a specified rack height.

In an example, the modular equipment chassis 100 includes the first top support 110A and the first bottom support 115A, and the other top and bottom supports are omitted. The top and bottom supports 110A and 115A are configured to span a length (e.g., in the direction of the Y axis as illustrated in FIG. 1) of the first and second side plates 120A and 120B and span a distance (e.g., in the direction of the X axis as illustrated in FIG. 1) between the first and second side plates 120A and 120B. In some other examples, the top and bottom supports 110A and 115A are configured to span only a portion (e.g., as shown in FIG. 1) of the length of the first and second side plates 120A and 120B and span the distance between the first and second side plates 120A and 120B. In an example, a plurality of top supports and a plurality of bottom supports are used when the top and bottom supports 110A and 115A span only a portion of the length of the first and second side plates 120A and 120B. In an example, the one or more top supports 110A, 1108, and 110C can be configured to be the same or substantially identical in size and shape to the one or more bottom supports 115A, 115B. In another example, the first top support 110A can be configured to be the same or substantially identical to the first bottom support 115A while the second and third top supports 110B and 110C are configured to be different than the second bottom support 115B and the third bottom support. Other combinations or configurations of the one or more top supports 110A, 110B, and 110C and the one or more bottom supports 115A, 115B can be used.

In an example, the one or more top supports 110A, 110B, and 110C and the one or more bottom supports 115A and 115B are configured to fit within a specified rack width dimension and a specified rack depth dimension. In an example, the specified rack dimensions correspond to a 19 inch (or 48.26 centimeter) rack, such as provided by Electronic Industries Alliance standard EIA-310-D or Consumer Electronics Association standard CEA-310-D, or the specified rack dimensions correspond to a 23 inch (or 58.42 centimeter) rack. Other standard and nonstandard dimensions can similarly be used.

In an example, the first side plate 120A and the second side plate 120B are configured to fit within a specified rack depth dimension and can have a specified incremental rack height unit dimension. In an example, the specified rack height is an incremental rack height unit dimension of the first side plate 120A and second side plate 120B is in increments of 1 U. The unit of measurement U is called a rack unit and is about 1.75 inches (or about 4.45 centimeters). In an example, the first side plate 120A has a 3 U dimension, and the modular equipment chassis 100 can have an overall height of 3 U, which is equivalent to an overall height of 5.25 inches (or about 13.34 centimeters). Thus the one or more top supports 110A, 110B, and 110C, one or more bottom supports 115A and 115B, and first and second side plates 120A and 120B can be selected to provide a chassis that can fit within one or more different “standard” or nonstandard racks.

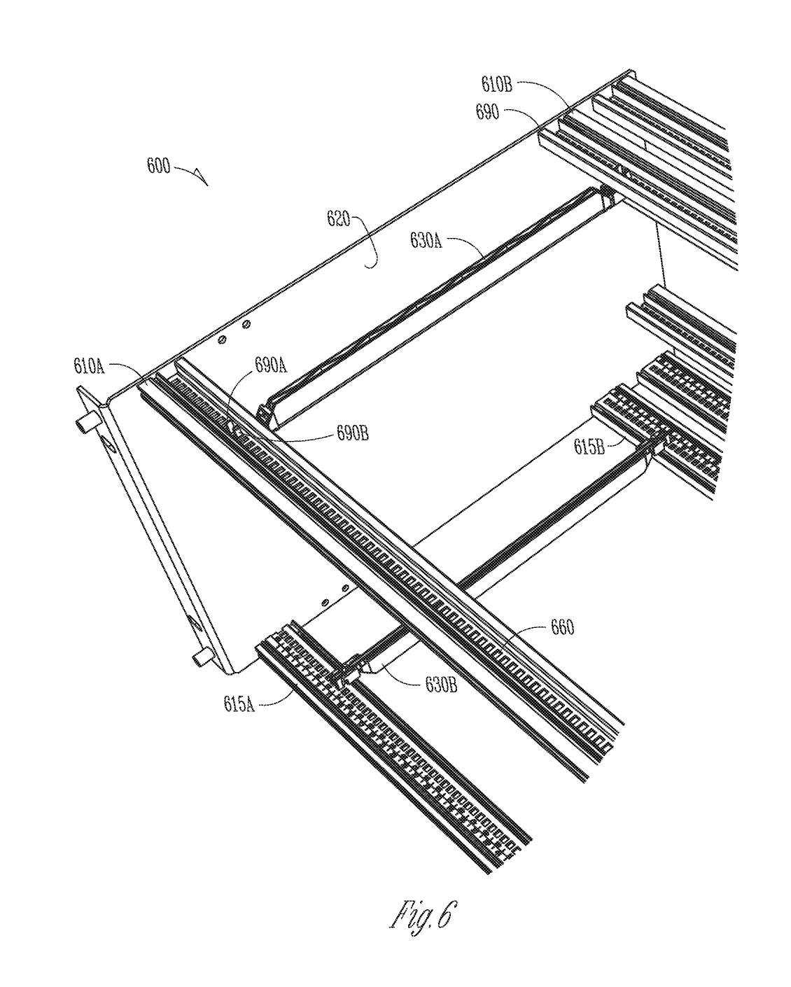

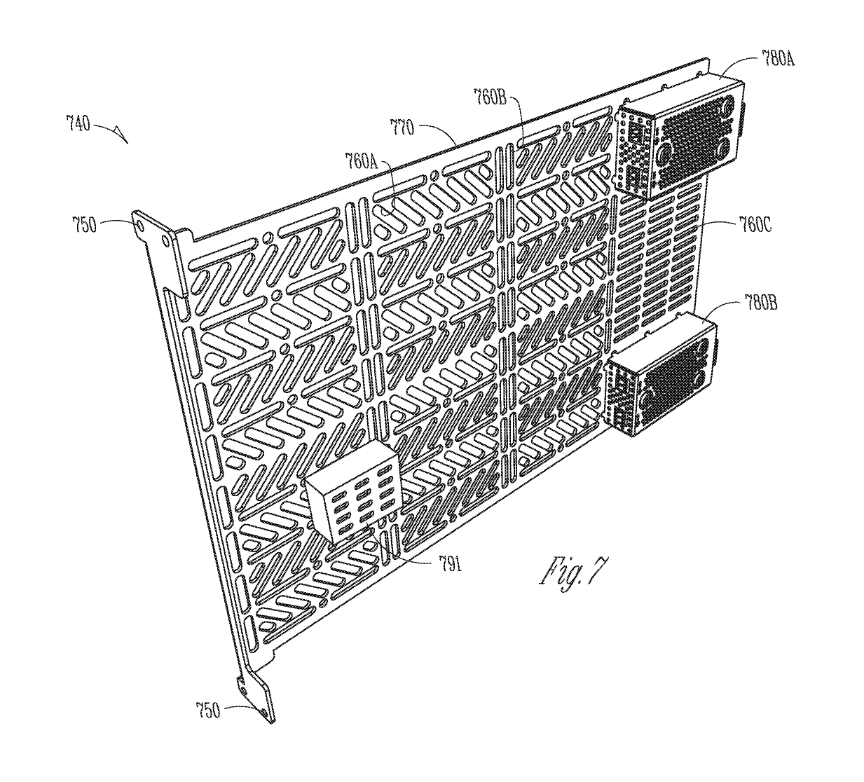

In an example, the modular equipment chassis 100 includes one or more guide rails 130 configured to be coupled with at least one of the top supports 110A, 110B, and 110C or at least one of the bottom supports 115A and 115B. In an example, the one or more guide rails 130 are configured to receive and/or retain at least a portion of the first electronic appliance mount 140. The first electronic appliance mount 140 can include side edge portions that are configured to be received by one or more mounting brackets or guide rails, such as further discussed below in the examples of FIGS. 4 and 5.

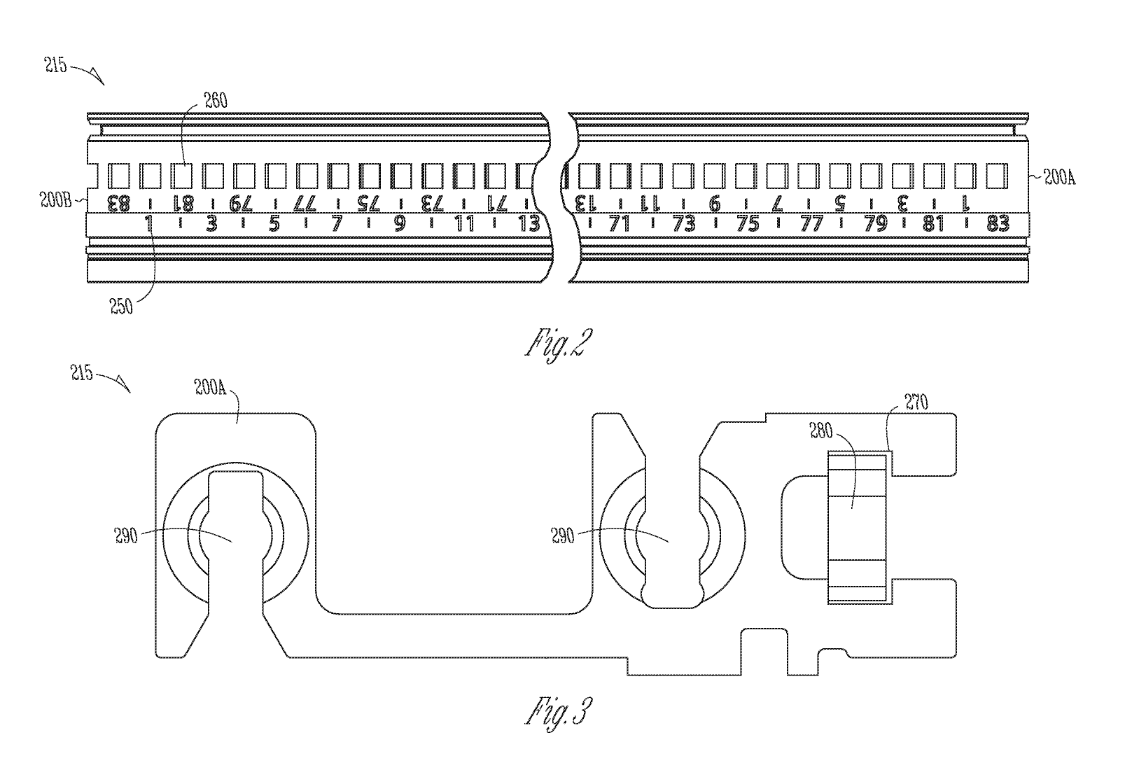

FIG. 2 is a perspective view of an example of a support 215 for a modular equipment chassis (e.g., the modular equipment chassis 100 of FIG. 1). For example, the support 215 can correspond to, or be configured for use as, the first top support 110A or the first bottom support 115A in the example of FIG. 1. In an example, the support 215 includes a first end 200A, an opposite second end 200B, one or more positional indicia 250, and one or more mounting locations 260 provided in visual correspondence with the positional indicia 250. In an example, the indicia 250 are alphanumerical characters (e.g., numbers, letters, symbols, or a combination thereof) that are substantially aligned with individual ones of the one or more mounting locations 260. The indicia 250 can indicate the individual mounting locations 260, such as to allow a user to readily identify a particular one of the mounting locations 260, such as in relation to one or more other ones of the mounting locations 260. Stated another way, the indicia 250 provide a visual or pictorial representation of the mounting locations 260.

In an example, the one or more mounting locations 260 are intermittently, or incrementally, spaced along the support 215 from its first end 200A to its opposite second end 200B. The spacing between the one or more mounting locations 260 can be regular or uniform, or can be irregular. In an example, the one or more mounting locations 260 are provided on only a portion of the support 215 and extend only partially between the first end 200A and the opposite second end 200B. The one or more mounting locations 260 shown in the example of FIG. 2 include a series of square perforations in the support 215 that are spaced apart at a specified, regular or periodic distance or interval. Other perforation shapes or spacings can be similarly used. For example, the one or more mounting locations 260 can include a series of circular perforations that are spaced apart at a specified distance. In another example, the one or more mounting locations 260 includes a channel that extends along substantially all or a portion of a length of the support 215.

In an example, the one or more mounting locations 260 are threaded or otherwise configured to engage with, and retain, a fastener (e.g., a screw, a bolt, a stud, a nut, a rivet, or the like). In an example, and as discussed in greater detail herein, the one or more mounting locations 260 are configured to engage with, and retain (e.g., couple with), a guide rail (e.g., the one or more guide rails 130 of FIG. 1). In another example, the support 215 includes a slot that is configured to receive a guide rail and allow the guide rail to translate within the slot. The slot can extend in the length direction of the support 215, such that the received guide rail is movable along the length of the support 215.

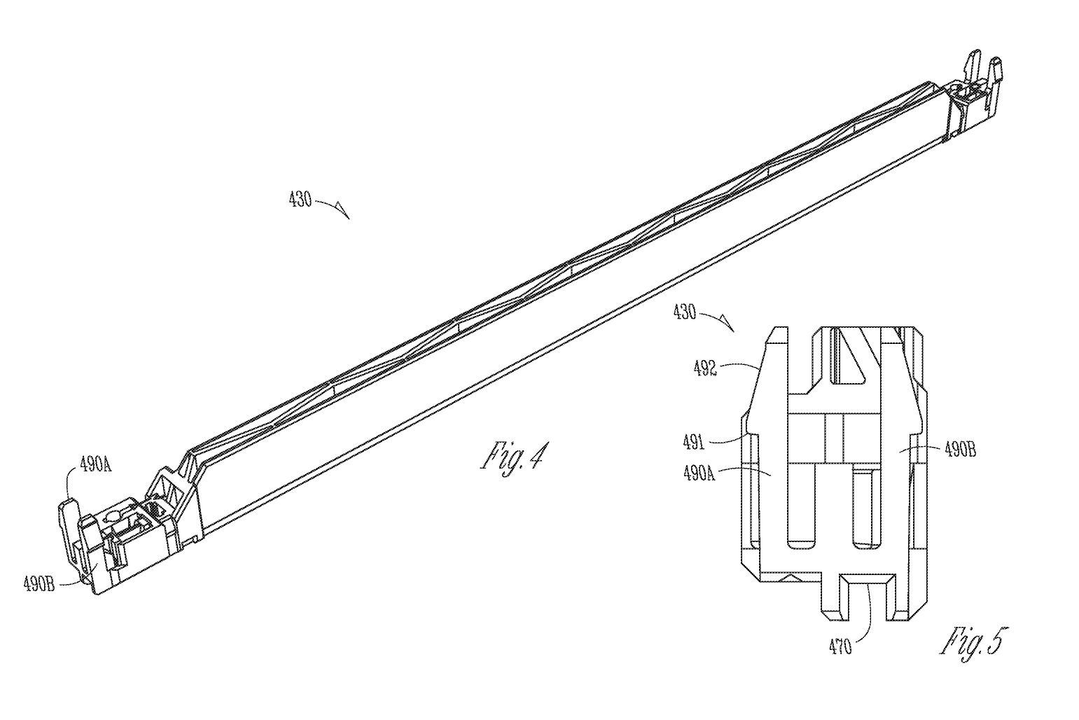

FIG. 3 is a perspective view of the first end 200A of the support 215 of FIG. 2. In an example, the support 215 includes a slot 270, an attachment member 280, and one or more side plate fixation holes 290. In an example, the slot 270 is configured to receive the attachment member 280. In an example, and as discussed herein, the attachment member 280 includes one or more attachment holes (not shown). The attachment holes can be configured to engage with, and retain, a fastener (e.g., screw, bolt, clip, pin, or the like). The attachment holes can be used to couple an electronic appliance mount (e.g., electronic appliance mount 140 of FIG. 1) to the attachment member 280, and thereby couple the electronic appliance mount to the support 215.

In an example, the side plate fixation holes 290 are configured to engage with a fastener. Both the first end 200A and the opposite second end (not shown) of the support 215 can include one or more side plate fixation holes 290.The fastener can engage with threads cut into the side plate fixation holes 290. In an example, side plates (e.g., first and second side plates 120A, B of FIG. 1) include holes that correspond in location to the side plate fixation holes 290. A user can insert a fastener through the holes in the side plate and couple the fastener with the side plate fixation holes 290, thereby coupling the side plate with the support 215. Similarly, the fixation holes can be used to couple a side plate with a top support.

FIG. 4 is a perspective view of an example of a guide rail 430. The guide rail 430 can be configured to be coupled with at least one of the one or more top supports 110A, 110B, and 110C or at least one of the bottom supports 115A and 115B. The guide rail 430 can be configured to receive and/or retain at least a portion of an electronic appliance mount (e.g., the first electronic appliance mount 140). In an example, the guide rail 430 includes one or more tabs 490A and 490B. In an example, the one or more tabs 490A and 490B are located on the side ends of the guide rail 430. In an example, the one or more tabs are configured to engage with, and be retained by, a mounting location (e.g., the one or more mounting locations 260 of FIG. 2). The guide rail 430 can include a length axis. The tabs can protrude orthogonal to the length axis. The tabs can be configured to mate with, or be received by, one or more mounting locations (e.g., mounting locations 260 of the support 215 of FIG. 2). In an example, each end of the guide rail 430 includes a pair of the tabs 490A and 490B, and the tabs 490A and 490B are configured to mate with, or be received by, a corresponding pair of mounting locations 260 in the support 215. Some additional features of the guide rail 430 and tabs 490A and 490B are discussed below in the example of FIG. 5.

FIG. 5 is a side view of the guide rail 430 of FIG. 4 with the tabs 490A and 490B facing upward in the figure. In one example, the guide rail 430 includes a recess 470 and the one or more tabs 490A and 490B. The recess 470 can extend substantially along a length (e.g., along the length axis) of the guide rail 430. The recess 470 can be configured to receive at least a portion of an electronic appliance mount (e.g., the first electronic appliance mount 140 of FIG. 1). For example, the recess 470 can include a 441 base and sidewalls that can receive a side edge portion of an electronic appliance mount. In an example, the recess extends along only a portion of the guide rail 430.

In an example, each of the one or more tabs 490A and 490B includes a flange 491 and a tapered surface 492. As further discussed herein, the tapered surface 492 can be configured to facilitate the insertion of a tab into a mounting location (e.g., the one or more mounting locations 260 of FIG. 2), such as by helping to guide or center the body of the tabs 490A and 490B as the tabs 490A and 490B slide into the mounting locations. The flange 491 can be configured to engage with a portion of the mounting location. In an example, a mounting location includes a through-hole, and the flange 491 includes an outer-facing surface that is configured to mate against an inner surface of the through-hole of the mounting location. The engagement of the flange 491 with the through-hole of the mounting location can be one of multiple different features that help to secure or retain the tabs 490A and 490B within their respective mounting locations. The engagement of the flange 491 with the through-hole of the mounting location can be one of multiple different features that help to secure or retain the guide rail 430 with a support (e.g., the support 215 of FIG. 2)

In an example, the one or more tabs 490A and 490B can be cantilevered, that is, a base or end portion of a tab can be coupled to the guide rail 430 body with an opposite end portion of the tab freely projecting away from the guide rail 430 body. When one or more of the tabs 490A and 490B are cantilevered, the one or more tabs 490A and 490B can move or deflect when subjected to a force applied orthogonally to the extension of the cantilever. For example, a user attempting to insert the guide rail 430 can move or deflect one or more the tabs 490A and 490B to help insert the tab into a mounting location. In some examples, the recess 470 can extend substantially along a length of the guide rail 430 and is configured to receive at least a portion of an electronic appliance mount (e.g., electronic appliance mount 140 of FIG. 1). In an example, the recess extends along only a portion of the guide rail 430.

FIG. 6 is a perspective view of a portion of a modular equipment chassis 600 with first and second guide rails installed therein. The modular equipment chassis 600 includes a first top support 610A, a second top support 610B; a first bottom support 615A, a second bottom support 615B; a first side plate 620; a first guide rail 630A; a second guide rail 630B; one or more mounting locations 660; and one or more tabs 690A and 690B on each of the guide rails. In an example, the one or more top supports 610A and 610B and the one or more bottom supports 615A and 615B are coupled to different, spaced-apart locations on the first side plate 620 and span the distance between the first side plate 620 and a second side plate (not shown). In an example, the first guide rail 630A is configured to extend between the first and second top supports 610A, B. That is, the tabs 690A and 690B of the first guide rail 630A are mated with the first and second top supports 610A and 610B. The first guide rail 630A can additionally or alternatively be configured to extend between (e.g., to mate with) other supports (e.g., a third or fourth top support). The second guide rail 630B is configured to extend between the first and second bottom supports 615A and 615B. The second guide rail 630B can additionally or alternatively be configured to extend between other supports (e.g., a third or fourth bottom support).

In an example, the tabs 690A and 690B that extend from both of the first and second guide rails 630A and 630B engage with, and are retained by the one or more mounting locations 660 of the top supports 610A and 610B and the bottom supports 615A and 615B. The tabs 690A and 690B can extend from both a first end and a. second end of the first or second guide rails 630A or 630B. Although the tabs 690A and 690B are shown in FIG. 6 as engaging with the mounting locations 660, other mounting features or techniques can be used. For example, the first guide rail 630A (and similarly the second guide rail 630B) can be configured to couple with the mounting locations using one or more fasteners (e.g., screws, bolts, studs, nuts, pins. clips, or the like). The fasteners can pass through a portion of the first guide rail 630 and the mounting locations 660, thereby coupling the first guide rail to the first and second top supports 610A, B. In an example, the top supports 610A, B are configured to include additional slots, wherein the first guide rail 630A is configured to translate within the slot. The first guide rail 630A can be further configured to selectively lock (e.g., a user is able to engage and disengage the locking mechanism) into place once the first guide rail 630 is translated completely into the slot. In an example, the first guide rail 630A can include a locking mechanism. The locking mechanism can engage with, and be retained by, a portion of the guide rail 430, or with a support (e.g., support 215 of FIG. 2).

In an example, the first and second guide rail 630A, B in the example of FIG. 6, provide a corresponding pair of guide rails. The pair of guide rails are respectively coupled with the top supports 610A and 610B and the bottom supports 615A and 615B at corresponding positions, that is, at mounting locations that are sufficiently aligned such that an electronic appliance mount can be received by both of the guide rails. In an example, the first guide rail 630A is coupled with the first and second top supports 610A and 610B at a first position that corresponds with a first and second indicia (e.g., indicia 250 of FIG. 2), such as indicia “11” and “12”. For example, the first guide rail 630A shown in FIG. 6 is coupled with the first and second top supports 610A and 610B at numerical indicia 11 and 12 (the numerical indicia are not shown in the example of FIG. 6). The first and second indicia indicate mounting locations 660 of the first and second top supports 610A and 610B. The first guide rail 630A has two tabs 690A and 690B. The two tabs 690A and 690B engage with two mounting locations 660 and thereby locate the first guide rail 630A at the first position.

Similarly, the second guide rail 630B (of the corresponding pair of guide rails) is coupled with the first and second bottom supports 615A and 615B at a second position that corresponds with the same first and second indicia (e.g., 11 and 12) as the first guide rail 630A. Stated another way, the first and second guide rails 630A and 630B can be a corresponding pair when they are located at substantially the same position relative to the side plates and/or ends of the respective supports. The corresponding pair of guide rails, when mounted, are separated by a distance (e.g., the distance between the top supports 610A and 610B and bottom supports 615A and 615B), such that a vertical plane or slot is provided between the first and second guide rails 630A and 630B. However, other orientations, such as slanted or horizontal orientations in which one of the guide rails is offset from the other can similarly be used.

In an example, the first and second guide rails 630A, B are members of respective first and second sets of guide rails. The first set of guide rails includes a plurality of guide rails (e.g., two or more first guide rails 630A). The second set of guide rails includes a plurality of guide rails (e.g., two or more second guide rails 630B). The first set of guide rails include guide rails that are coupled to a top support (e.g., first top support 110A of FIG. 1), but each of the guide rails are coupled to different locations (e.g., spaced apart). The second set of guide rails include guide rails that are coupled to a bottom support (e.g., first bottom support 115A of FIG. 1), but each of the guide rails are coupled to different locations (e.g., spaced apart). The guide rails of the first and second set of guide rails can be coupled to different locations on the top and bottom supports, respectively, such that the guide rails contained in a set are parallel in relation to each other. The first and second set of guide rails can be included in a plurality of corresponding pairs of guide rails (e.g., a plurality of guide rail pairs).

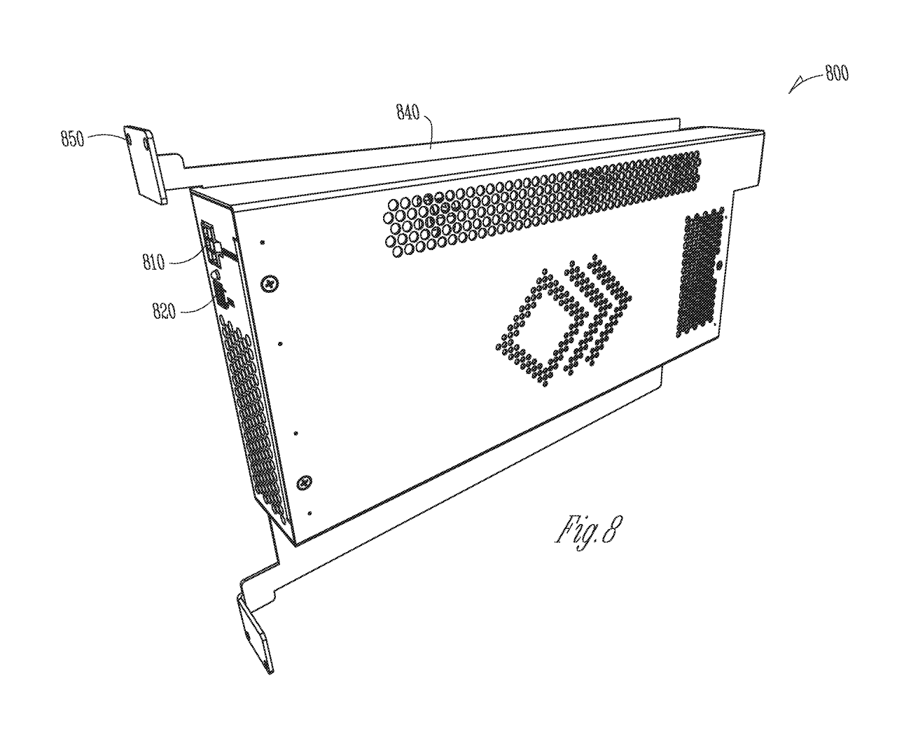

FIG. 7 is a perspective view of an example of an electronic appliance mount 740. In an example, the electronic appliance mount 740 includes one or more mount attachment holes 750, a plurality of mounting features 760A-C, a perimeter edge portion 770, a first power regulator 780A, a second power regulator 780B, and an enclosed electronic appliance 791. The perimeter edge portion 770 can also be referred to as a side edge portion. In the example of FIG. 7 the electronic appliance mount 740 includes first and second power regulators 780A and 780B. Additional or fewer power regulators can be used.

In an example, the electronic appliance mount 740 includes one or more features configured to secure an electronic appliance to the electronic appliance mount. In an example, the enclosed electronic appliance 791 can be secured or fastened (e.g., coupled) to the electronic appliance mount 740, such as using an attachment mechanism. The attachment mechanism can include one or more of a zip tie, a hook-and-loop fastener (e.g., Velcro), single-sided or double-sided adhesive tape, or any other device or material that can secure or fasten an enclosed electronic appliance 791 to the electronic appliance mount 740. In yet another example, the enclosed electronic appliance 791 is coupled to the electronic appliance mount 740 by using one or more fasteners. The one or more fasteners can pass through the one or more mounting features 760A-C and thereby couple the enclosed electronic appliance 791 to the electronic appliance mount 740. The method and structure explained above can uniformly secure (e.g., in an organized manner) one or a plurality of enclosed electronic appliances, such as enclosed electronic appliance 791.

The electronic appliance mount 740 can be configured to couple with an electronic appliance. In an example, the electronic appliance is enclosed by an enclosure (e.g., a case, chassis, package, or the like). In another example, the electronic appliance does not include an enclosure (e.g., the electronic appliance is a printed circuit board with electrical components coupled therewith). In yet another example, the electronic appliance is partially enclosed by an enclosure.

The enclosed electronic appliance 791 can be mounted in a vertical manner. Vertical mounting of an enclosed electronic appliance 791 can include rotating an enclosed electronic appliance 791 that would normally lay flat against a base surface with a low profile, 90 degrees from its normal orientation into a vertical orientation such that it can be placed into a modular equipment chassis (e.g., modular equipment chassis 100 of FIG. 1). Such vertical mounting of an enclosed electronic appliance 791 to the electronic appliance mount 740 allows for the efficient use of limited rack space by organizing one or more enclosed electronic appliances in a uniform manner. In an example, the multiple enclosed electronic appliances can have different dimensions and can be mounted to an electronic appliance mount 740 with consistent dimensions. In an example, vertical mounting of the enclosed electronic appliance 791 can decrease the operating temperature of the enclosed electronic appliance 791 (e.g., by increasing a rate of natural convection or heat dissipation). Decreased operating temperatures within an enclosed electronic appliance 791 can improve the durability or reliability of the enclosed electronic appliance 791.

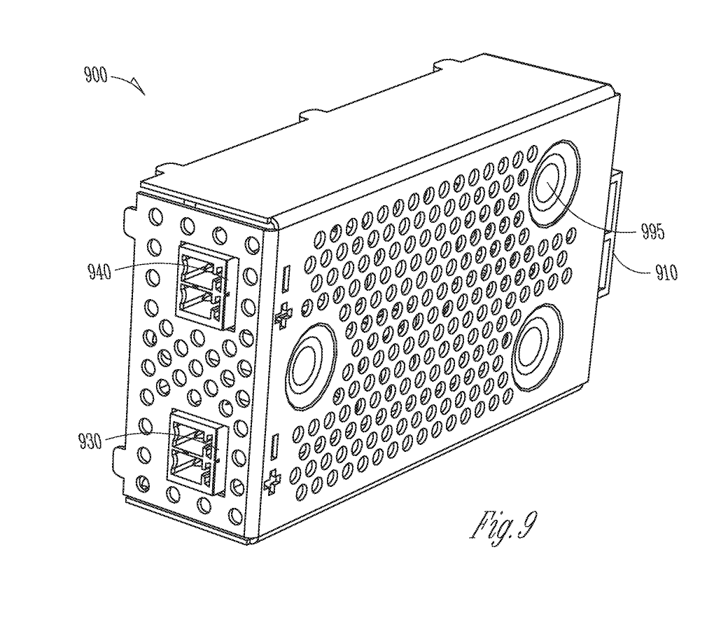

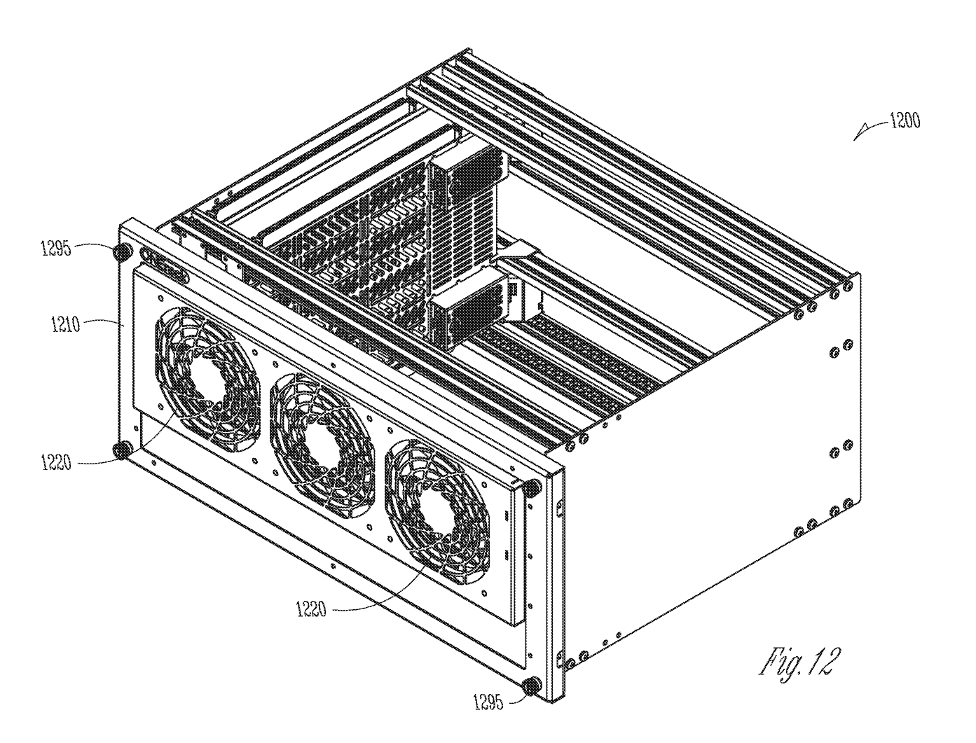

FIG. 8 is a perspective view of an example of a power supply module 800. In one example, the power supply module 800 includes at least one power input 810 and at least one power output 820. In an example, the power supply module 800 is coupled to an electronic appliance mount 840. in an example, the electronic appliance mount 840 couples the power supply module 800 with a guide rail (e.g., guide rail 1130 of FIG. 11). in some examples, the power supply module 800 includes a data input, such as an RJ-45 connector or a RS-232 serial connector for coordinating control signals to or from the power supply module 800. The power input 810 can be can be coupled to an AC or DC power source, such as a 120V AC outlet, and can be hard wired or can include a plug for transportability. The power input 810 can be electrically coupled to at least one AC/DC converter that is configured to supply a first power signal to the power output 820. The AC/DC converter can be internal to the power supply module 800.

In an example, the first power signal at the power output 820 can be the same as the power signal received at the power input 810. In another example, the first power signal at the power output 820 can be different than the power signal at the power input 810. In an example, the power input 810 receives a 120 volt alternating current (“AC”) signal, a power conversion circuit on-board the power supply module 800 converts the received AC signal, and then the power supply module 800 provides, via the power output 820 a first converted power signal that is a 12 volt direct current signal. Other power signal conversions (e.g., signal magnitude step-up or step-down, signal frequency change, signal type, etc.) can be similarly performed by the power supply module 800 to provide one or more power output signals to power one or more electronic appliances in the chassis.

In an example, use of the power supply module 800 in a modular equipment chassis can help reduce a number of different power supplies that may otherwise be required to operate the one or more enclosed electronic appliances located within the modular equipment chassis. For example, an enclosed electronic appliance can be provided with its own dedicated power supply. The power supply provided by the appliance's manufacturer may be bulky or cumbersome to install, especially when dozens of enclosed electronic appliance mounts are located within the modular equipment chassis. The elimination or avoidance of numerous, often large and cumbersome, power supplies and providing a uniform and standardized electrical connection system for enclosed electronic appliances can help allow for the efficient use of valuable rack space. The power supply module 800 can be configured to directly supply power to the enclosed electronic appliances, or indirectly supply power to the enclosed electronic appliances through the use of a power regulator.

The power supply module 800 can supply different power signals to respective different power supply electrical connections, such as via the power output 820. That is, the power output 820 can include multiple different electrical connections that provide the same or different power signals, such as having the same or different power signal characteristics. For example, the power supply module 800 can also supply differing power levels to multiple power supply electrical connections, such as power output 820. The power supply functionality described above can allow for the power supply to provide the same power level to one or a plurality of power supply electrical connections, such as power output 820. The power supply module 800 can simultaneously provide a different power level to other power supply connections, or to a plurality of power supply electrical connections, such as power output 820.

In an example, multiple power supplies can be provided in the modular equipment chassis and operated in parallel, such as to provide a redundant power source to the enclosed electronic appliances in the event that one of the power supplies fails. In an example, the power supplies can be operated in series to combine their respective power output signals.

In an example, the power supply module 800 is remotely-operable by a user, such as by using the RJ-45 connector or the RS-232 serial connector to change, or adjust, the power level delivered to one or a plurality of power supply electrical connections, such as power output 820. The remote control feature of the power supply module 800 can allow the user to turn the power on or off to one or a plurality of power supply electrical connectors, such as power output 820. The remote control feature of the power supply module 800 can also allow a user to monitor the operation of the power supply module 800 to check for problems or to address problems as they arise. The remote operation features of the power supply module 800 can allow for a user to power cycle an enclosed electronic appliance remotely, which can often cure an issue that has occurred with an enclosed electronic appliance. The remote operation features can save the user time and money in troubleshooting issues with an enclosed electronic appliance.

In an example, one or more of the power supply functions or features can be operated by a user via controls on the power supply module 800 itself. For example, the power supply module 800 can include a plurality of buttons for operating and altering the functions and features of the power supply module 800.

FIG. 9 is a perspective view of an example of a power regulator 900. The power regulator can include a signal input 910, a control input, a first signal output 930, a second signal output 940, and regulator fixation holes 995. In an example, the power regulator 900 further converts power signals from a power supply (e.g., power supply module 800 of FIG. 8) in order to reduce the need for additional, full-blown power supply units in the modular equipment chassis. The power regulator 900 can be considered an enclosed electronic appliance. In an example, the signal input 910 is in electrical communication with a power output (e.g., power output 820 of FIG. 8) and can receive a first power signal. The power regulator 900 can convert the first power signal into a second power signal. In some examples, the second power signal is different than the first power signal (e.g., signal magnitude is stepped-up or stepped-down, signal frequency change, signal type, etc.). The power regulator 900 can convert the first power signal into a third power signal. The power regulator 900 can convert the first power signal into a plurality of power signals. Stated another way, the power regulator 900 can be configured to receive a first power signal, and alter the voltage, current, impedance, or other electrical signal properties of the first power signal and convert it to one or more other power signals.

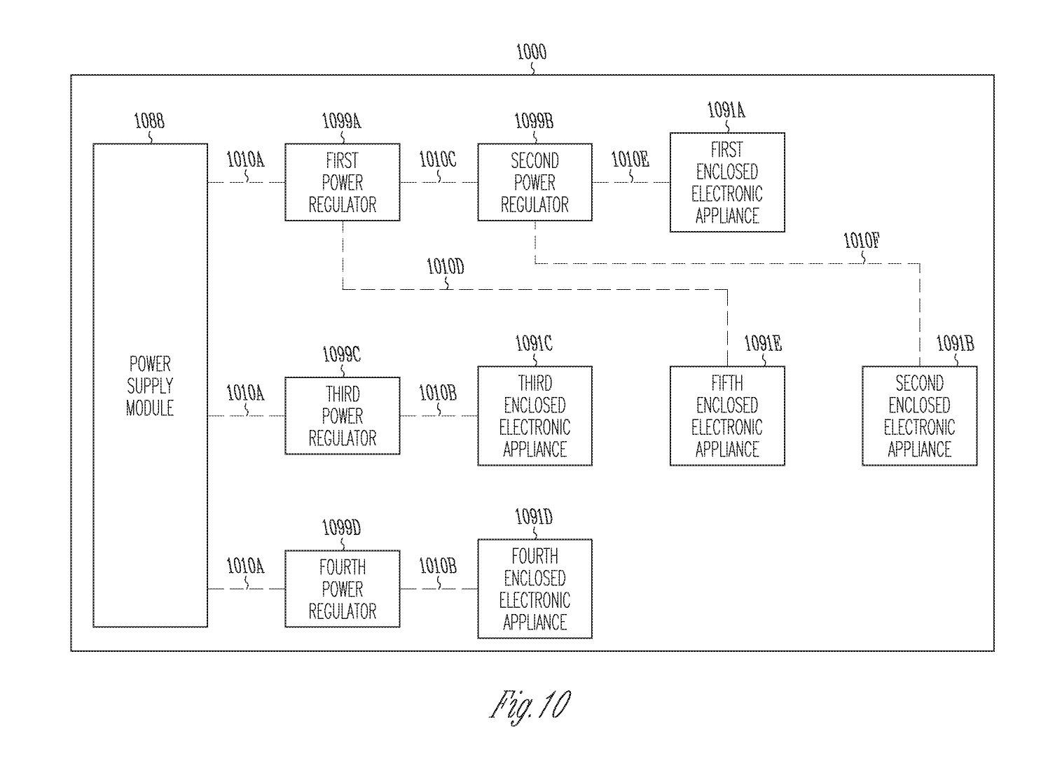

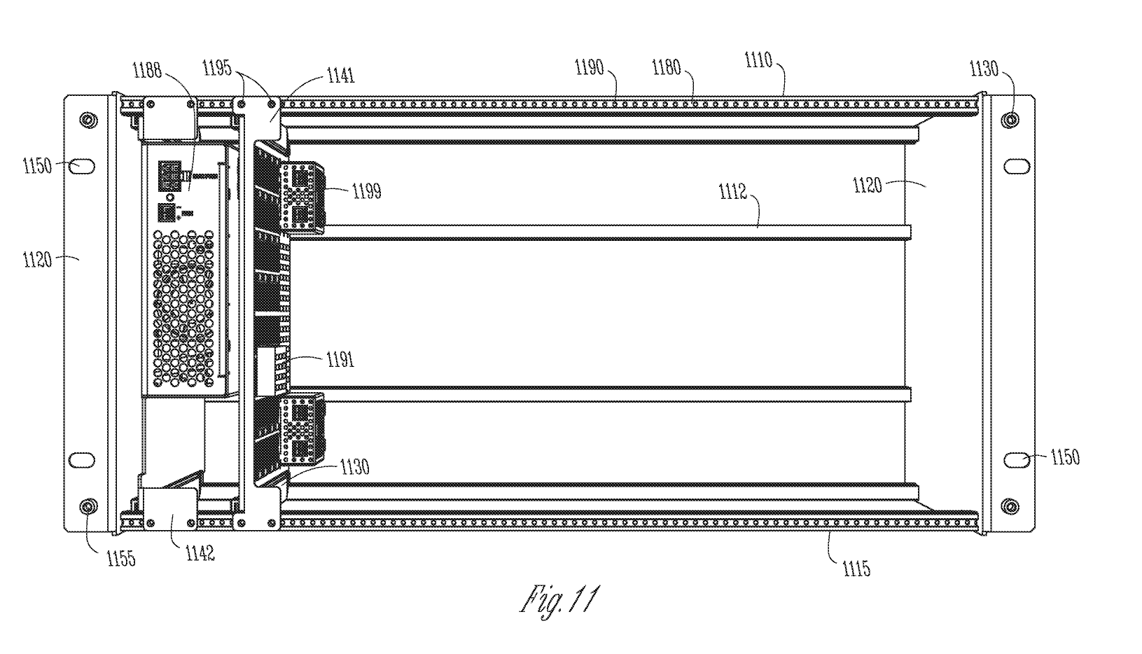

In one example, the power regulator 900 is configured to output a second power signal at the first signal output 930 and at the second signal output 940. In another example, the power regulator 900 is configured to output a first power signal at the first signal output 930 and output a second power signal at the second signal output 940. In yet another example, the power regulator 900 is configured to output a second power signal at the first signal output 930 and output a third power signal at the second signal output 940. Additional signal outputs can be used. In these preceding examples, the power regulator 900 receives the first power signal from a power supply (e.g., from the power supply module 800 of FIG. 8). The power regulator can be configured to regulate the first power signal in some manner (e.g., increase or decrease the voltage) or transmit the first power signal to an enclosed electronic appliance or another power regulator. Stated another way, and as discussed with reference to FIG. 10, one or more power regulators can be wired in parallel or daisy-chained together. In an example, the power regulator 900 is used to provide a regulated power source to one or more enclosed electronic appliances (e.g., enclosed electronic appliance 791 of FIG. 7).

In an example, and similar to the power supply module 800 of FIG. 8, the power regulator 900 is configured to be remotely-operable by a user. In an example, the control input is configured to receive a control signal. The control signal can represent a desired change in the power level delivered to one or a plurality of power supply electrical connections, such as first signal output 930. The remote control feature of the power regulator 900 can allow the user to turn on or turn off a power signal provided to one or more power supply electrical connectors, such as using the second signal output 940. The remote control feature of the power regulator 900 can also allow a user to monitor the operation of the power regulator 900 to check for problems or to address problems that may arise.

In an example, the power regulator 900 is configured to be mounted to an electronic appliance mount (e.g., electronic appliance mount 740 of FIG. 7). Regulator fixation holes 995 can be used to mount or couple the power regulator to the electronic appliance mount. In another example, the power regulator 900 is configured to couple with either the top or bottom supports (top and bottom supports 110A and 115A of FIG. 1) or with an intermediary support (e.g., intermediary support 1112 of FIG. 11). In an example, the power regulator 900 spans between a top support and an intermediary support and is fastened to the top and intermediary support, such as by fasteners.

In an example, a modular equipment chassis (e.g., the modular equipment chassis 100 in the example of FIG. 1) includes a signal distribution plug to simplify interconnection of power regulators with power supplies. In an example, the signal distribution plug is configured to couple with a power regulator 900 at the signal input 910, wherein the power regulator is coupled to an electronic appliance mount. The coupling of the signal distribution plug with the power regulator can ease the electrical interconnections required for the modular equipment chassis. In an example, the signal distribution plug moves a termination point for the power regulator 900 from the electronic appliance mount to a rear side of the modular equipment chassis, thereby improving access to the termination point by a user. In an example, the signal distribution plug is configured to reroute an electrical signal from a power supply (e.g., power supply module 800 of FIG. 8), to additional power regulators or to enclosed electronic appliances.

In an example, the signal distribution plug is configured to couple with either the top or bottom supports (top and bottom supports 110A and 115A of FIG. 1) or with an intermediary support (e.g., intermediary support 1112 of FIG. 11). In an example, the power distribution plug spans between a top support and an intermediary support and is fastened to the top and intermediary support, such as by fasteners.

FIG. 10 is a schematic diagram of multiple power regulators coupled to a power supply within a modular equipment chassis 1000. In one example, the modular equipment chassis 1000 includes a power supply module 1088, a plurality of power regulators 1099A-E, a first power signal 1010A, a second power signal 1010B, a third power signal 10100, a fourth power signal 1010D, a fifth power signal 1010E, and a sixth power signal 1010F. In an example, the power supply module 1088 is configured to output a first power signal 1010A. The first power signal 1010A can be electrically communicated to the power regulators 1099A-D through the use of one or more conductors.

In an example, the third and fourth power regulators 1099C and 1099D each receive a first power signal 1010A from the power supply module 1088 and convert the first power signal into a second power signal 1010B. The third and fourth power regulators 1099C and 1099D can provide the second power signal 1010B to a third and fourth enclosed electronic appliance 1091C and 1091D, respectively.

In an example, two or more power regulators are daisy chained together. The first power regulator 1099A is configured to be in electrical communication with the power supply module 1088 and receive the first power signal 1010A. The first power regulator 1099A is also configured to be in electrical communication with the second power regulator 1099B. The first power regulator 1099A can be configured to transmit a third power signal 10100 to the second power regulator 1099B. The third power signal 1010C can be the same as, or different from, the first power signal 1010A.

In an example, the first power regulator 1099A can be configured to convert the first power signal 1010A into a fourth power signal 1010D and transmit the fourth power signal 1010D to a fifth enclosed electronic appliance 1091E, or to other power regulators. The second power regulator 1099B can be configured to convert the third power signal 1010D into a fifth power signal 1010E. The second power regulator 1099B can provide the fifth power signal 1010E to a first enclosed electronic appliance 1091A. The second power regulator 1099B can be further configured to convert the third power signal 1010C into a sixth power signal 1010F. The second power regulator 1099B can provide the sixth power signal 1010E to a second enclosed electronic appliance 1091B.

In an example, the first and third power regulators 1099A and 1099C are coupled to the same electronic appliance mount. In another example, the first and third power regulators 1099A and 1099C are coupled to different electronic appliance mounts. In yet another example, each of the first, second, third, and fourth power regulators 1099A-D are coupled to different electronic appliance mounts.

FIG. 11 is a perspective view of an example of a power supply module, a power regulator, and an electronic appliance mount in a modular equipment chassis 1100. The modular equipment chassis 1100 includes one or more top supports 1110, one or more intermediary supports 1112, one or more bottom supports 1115, one or more side plates 1120, one or more guide rails 1130, a first electronic appliance mount 1141, a second electronic appliance mount 1142, one or more chassis fixation holes 1150, one or more studs 1155, an attachment member 1180, a power supply module 1188, attachment holes 1190, an enclosed electronic appliance 1191, and a power regulator 1199. The one or more studs 1155 can be configured to couple with a fastener. The one or more studs 1155 can be configured to mate with, and retain (using a fastener), a cover that is configured to limit physical access to the modular equipment chassis.

In an example, the electronic appliance mount 1140 is coupled to the guide rail 1130. In some examples, a plurality of electronic appliance mounts are coupled with the guide rail 1130. Stated another way, more than one electronic appliance mount 1140 can be coupled to the guide rail 1130. In one example, the electronic appliance mount is coupled to the guide rail using fasteners (e.g., screws, bolts, studs, nuts, pins, clips, or the like). As previously discussed herein, in some examples, the guide rail 1130 includes a recess (see e.g., the recess 470 in the example of FIG. 4) that is configured to receive an appliance mount therein. In an example, the electronic appliance mount 1140 is configured to translate within the recess of the guide rail 1130. In an example, a corresponding pair of guide rails is used, and the electronic appliance mount 1140 is configured to translate within respective recesses of first and second guide rails of the corresponding pair of guide rails. The translation of the electronic appliance mount 1140 within the recess can couple the electronic appliance mount 1140 with the guide rail 1130.

In an example, the modular equipment chassis 1100 shown in FIG. 11 includes two corresponding pairs of guide rails. The first electronic appliance mount, including the enclosed electronic appliance 1191 and the power regulator 1199, is coupled to a first corresponding pair of guide rails. In one example, the attachment member 1180 includes attachment holes 1190 configured to receive and retain a fastener. In some examples, the first electronic appliance mount 1141 is coupled to the attachment holes 1190 of the attachment member 1180 with mount fasteners 1195, thereby coupling the first electronic appliance mount 1141 to the top and bottom supports 1110, 1115. The second electronic appliance mount 1142 is similarly coupled to a second corresponding pair of guide rails and the top and bottom supports 1110, 1115.

As described previously herein, the guide rails can be positioned at various locations along the top and bottom supports 1110 and 1115. In an example, the attachment holes 1190 are aligned with various indicia (not shown) located on the top and bottom supports 1110, 1115. The positionable nature of the corresponding pairs of guide rails allows for versatility in the installation of enclosed electronic appliances within modular equipment chassis 1100. The versatility of the modular equipment chassis 1100 allows for enclosed electronic appliances with a wide range of dimensions to fit within the modular equipment chassis 1100, thereby increasing a number or density of enclosed electronic appliances mounted in the chassis, such as due to improved organization and space utilization.

FIG. 12 is a perspective view of an example of a modular equipment chassis 1200 with a cooling fan assembly installed. In one example, the modular equipment chassis 1200 includes a cover 1210 and cover fasteners 1295. In some examples, the cover 1210 includes one or more fans 1220. In an example, the cover is detachably coupled with the modular equipment chassis 1200. The cover 1210 can couple with the modular equipment chassis with the cover fasteners 1295 and studs (e.g., studs 1155 of FIG. 11). In an example, the cover provides a protective barrier that encloses at least a portion of the chassis. In yet another example, the one or more fans 1220 are configured to provide airflow across an electronic appliance mount (e.g., first electronic appliance mount 1141 of FIG. 1).

In one example, the one or more fans 1220 cool enclosed electronic appliances contained within the modular equipment chassis 1200. In some examples, the vertical mounting of one or more enclosed electronic appliances (e.g., enclosed electronic appliance 1191 of FIG. 11) allows for one compact cooling module (e.g., when the cover 1210 includes one or more fans 1220)to cool the one or more enclosed electronic appliances. In some examples, the positionable mounting of the guide rails allows for improved cooling efficiency within the modular equipment chassis 1200. Cooling efficiency is improved because the enclosed electronic appliances will be organized and the organization removes impediments mis-organized enclosed electronic appliances) to air flow within the modular equipment chassis 1200.

### VARIOUS NOTES & EXAMPLES

Example 1 can include or use subject matter such as a modular equipment chassis for an electronic equipment rack, the rack including a specified rack width dimension, and a specified rack depth dimension, such as can include or use a first top support and a first bottom support, wherein the top and bottom supports each include a plurality of corresponding mount locations; first and second side members, wherein the first side member is coupled to a first end of each of the first top support and the first bottom support, and wherein the second side member is coupled to an opposite second end of each of the first top support and the first bottom support, and wherein each of the first and second side members has a height corresponding to a specified rack height; and a first guide rail coupled with at least one of the first top support and the first bottom support at one or more of the mount locations, and wherein the first guide rail is configured to receive and retain at least a portion of a first electronic appliance mount.

Example 2 can include, or can optionally be combined with the subject matter of Example 1, to optionally include the first electronic appliance mount, wherein the first electronic appliance mount is coupled with the first guide rail.

Example 3 can include, or can optionally be combined with the subject matter of one or any combination of Examples 1 or 2 to optionally include a plurality of electronic appliance mounts, wherein the pluralityof electronic appliance mounts are coupled with the first guide rail.

Example 4 can include, or can optionally be combined with the subject matter of one or any combination of Examples 1 through 3 to optionally include that the first guide rail includes a recess that extends substantially along a length of the first guide rail and is configured to receive at least a portion of the first electronic appliance mount.

Example 5 can include, or can optionally be combined with the subject matter of one or any combination of Examples 1 through 4 to optionally include that the first electronic appliance mount is coupled with the first guide rail using at least one fastener.

Example 6 can include, or can optionally be combined with the subject matter of one or any combination of Examples 1 through 5 to optionally include a second guide rail, wherein the first guide rail is coupled with the first top support at a first mount location and wherein the second guide rail is coupled with the first bottom support at a second mount location that corresponds to the first mount location, and wherein the second guide rail is configured to receive and retain at least a portion of the first electronic appliance mount.

Example 7 can include, or can optionally be combined with the subject matter of one or any combination of Examples 1 through 6 to optionally include that each of the first and second guide rails includes a recess that extends substantially along a length of the respective guide rail and is configured to receive opposite side edge portions the first electronic appliance mount.

Example 8 can include, or can optionally be combined with the subject matter of one or any combination of Examples 1 through 7 to optionally include that the electronic appliance mount is configured to translate within the respective recesses of the first and second guide rails in a length direction of the guide rails.

Example 9 can include, or can optionally be combined with the subject matter of one or any combination of Examples 1 through 8 to optionally include that the specified rack height is an integer number of a specified rack height unit dimension.

Example 10 can include, or can optionally be combined with the subject matter of one or any combination of Examples 1 through 9 to optionally include a first set of guide rails that is aligned with a second set of guide rails, wherein: each of the first set of guide rails is respectively coupled to different mount locations on the first top support; and each of the second set of guide rails is respectively coupled to different mount locations on the first bottom support; and the first and second sets include the same number of guide rails.

Example 11 can include, or can optionally be combined with the subject matter of one or any combination of Examples 1 through 10 to optionally include that the guide rails of the first and second sets of guide rails are coupled to respective corresponding mount locations to provide a plurality of guide rail pairs, and wherein a plurality of electronic appliance mounts are respectively coupled to the corresponding guide rail pairs.

Example 12 can include, or can optionally be combined with the subject matter of one or any combination of Examples 1 through 11 to optionally include that the electronic appliance mount includes one or more features configured to facilitate attachment of an electronic appliance to the mount.

Example 13 can include, or can optionally be combined with the subject matter of one or any combination of Examples 1 through 12 to optionally include that the power supply is configured to provide a first power signal to one or more electronic appliances mounted to the electronic appliance mount.

Example 14 can include, or can optionally be combined with the subject matter of one or any combination of Examples 1 through 13 to optionally include a power regulator in electrical communication with the power supply and configured to convert the first power signal to a second power signal that is different than the first power signal, and to supply the second power signal to one or more electronic appliances in the chassis.

Example 15 can include, or can optionally be combined with the subject matter of one or any combination of Examples 1 through 14 to optionally include a signal distribution plug including one or more signal outputs and configured to receive the second power signal at a signal input and provide the second power signal to the one or more outputs.

Example 16 can include, or can optionally be combined with the subject matter of one or any combination of Examples 1 through 15 to optionally include that the power supply includes a data input configured to receive one or more control signals from a user or from a remote device, and wherein the power supply is configured to adjust a power signal output characteristic based on the received one or more control signals.

Example 17 can include, or can optionally be combined with the subject matter of one or any combination of Examples 1 through 16 to optionally include a cover that is coupleable with the modular equipment chassis, wherein the cover provides a protective barrier that encloses at least a portion of the chassis and includes one or more fans configured to provide airflow across the electronic appliance mount.

Example 18 can include, or can optionally be combined with the subject matter of one or any combination of Examples 1 through 17 to optionally include a second top support spaced apart from the first top support and coupled to the first and second side members; a second bottom support spaced apart from the first bottom support and coupled to the first and second side members; and wherein the first guide rail is coupled with either the first and second top supports or the first and second bottom supports.

Example 19 can include or use subject matter such as a modular equipment chassis system for an electronic equipment rack, the rack including a specified rack width dimension, and a specified rack depth dimension, the modular equipment chassis system, such as can include a first top support and a first bottom support, wherein the top and bottom supports include a plurality of corresponding mount locations; a first substantially planar side member coupled to a first side of the first top support and to a first side of the first bottom support, wherein the first side member has a height corresponding to a specified rack height; a second substantially planar side member coupled to a second side of the first top support and to a second side of the first bottom support, wherein the second side member has a height corresponding to the specified rack height; a first guide rail coupled with at least one of the first top support and the first bottom support, wherein the first guide rail is configured to couple with at least one of the mount locations, and the first guide rail is further configured to receive and retain at least a side edge portion of a substantially planar first electronic appliance mount; the substantially planar first electronic appliance mount, wherein the substantially planar first electronic appliance mount is coupled with the first guide rail; a power supply module coupled with the first guide rail, wherein the power supply is configured to provide a first power signal; and a power regulator configured to receive the first power signal from the power supply module and convert the first power signal to a second power signal that is different than the first power signal, and further configured to provide the second power signal to one or more electronic appliances in the chassis; and an enclosed electronic appliance coupled to the substantially planar first electronic appliance mount, wherein the enclosed electronic appliance is in electrical communication with the power regulator and is configured to receive the second power signal.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A modular equipment chassis for receiving, and retaining enclosed electronic appliances in an electronic equipment rack, the rack including a specified rack width dimension, and a specified rack depth dimension, the modular equipment chassis comprising:
a first top support and a first bottom support, wherein the top and bottom supports each include a plurality of corresponding mount locations;
first and second side members, wherein the first side member is coupled to a first end of each of the first top support and the first bottom support, and wherein the second side member is coupled to an opposite second end of each of the first top support and the first bottom support, and wherein each of the first and second side members has a height corresponding to a specified rack height;
a first guide rail coupled with at least one of the first top support and the first bottom support at one or more of the mount locations; and
a first electronic appliance mount coupled with the first guide rail, wherein the first electronic appliance mount is configured to be coupled with at least one enclosed electronic appliance using a non-conductive fastener.

2. (canceled)

3. The modular equipment chassis of claim 1, further comprising a plurality of electronic appliance mounts that includes the first electronic appliance mount and a plurality of guide rails that includes the first guide rail, wherein the plurality of electronic appliance mounts are respectively coupled with the plurality of guide rails at respective different locations along the first top support or the first bottom support.

4. The modular equipment chassis of claim 1, wherein the first guide rail includes a recess that extends substantially along a length of the first guide rail and is configured to receive at least a portion of the first electronic appliance mount.

5. The modular equipment chassis of claim 1, wherein the first electronic appliance mount is coupled with the first guide rail using at least one fastener.

6. The modular equipment chassis of claim 1, further comprising a second guide rail, wherein the first guide rail is coupled with the first top support at a first mount location and wherein the second guide rail is coupled with the first bottom support at a second mount location that corresponds to the first mount location, and wherein the second guide rail is configured to receive and retain at least a portion of the first electronic appliance mount.

7. The modular equipment chassis of claim 6, wherein each of the first and second guide rails includes a recess that extends substantially along a length of the respective guide rail and is configured to receive opposite side edge portions the first electronic appliance mount.

8. The modular equipment chassis of claim 7, wherein the electronic appliance mount is configured to translate within the respective recesses of the first and second guide rails in a length direction of the guide rails.

9. The modular equipment chassis of claim 1, wherein the specified rack height is an integer number of a specified rack height unit dimension.

10. The modular equipment chassis of claim 1, further comprising a first set of guide rails that is aligned with a second set of guide rails, wherein:
each of the first set of guide rails is respectively coupled to different mount locations on the first top support; and
each of the second set of guide rails is respectively coupled to different mount locations on the first bottom support; and
the first and second sets include the same number of guide rails.

11. The modular equipment chassis of claim 10, wherein the guide rails of the first and second sets of guide rails are coupled to respective corresponding mount locations to provide a plurality of guide rail pairs, and wherein a plurality of electronic appliance mounts are respectively coupled to the corresponding guide rail pairs.

12. The modular equipment chassis of claim 1, wherein the electronic appliance mount includes one or more features configured to facilitate attachment of an electronic appliance to the mount.

13. The modular equipment chassis of claim 1, further comprising a power supply coupled with the first guide rail, wherein the power supply is configured to provide a first power signal to one or more electronic appliances mounted to the electronic appliance mount.

14. The modular equipment chassis of claim 13, further comprising a power regulator in electrical communication with the power supply and configured to convert the first power signal to a second power signal that is different than the first power signal, and to supply the second power signal to one or more electronic appliances in the chassis.

15. The modular equipment chassis of claim 14, further comprising a signal distribution plug including one or more signal outputs and configured to receive the second power signal at a signal input and provide the second power signal to the one or more outputs.

16. The modular equipment chassis of claim 13, wherein the power supply includes a data input configured to receive one or more control signals from a user or from a remote device, and wherein the power supply is configured to adjust a power signal output characteristic based on the received one or more control signals.

17. The modular equipment chassis of claim 1, further comprising a cover that is coupleable with the modular equipment chassis, wherein the cover provides a protective barrier that encloses at least a portion of the chassis and includes one or more fans configured to provide airflow across the electronic appliance mount.

18. The modular equipment chassis of claim 1, further comprising:
a second top support spaced apart from the first top support and coupled to the first and second side members;
a second bottom support spaced apart from the first bottom support and coupled to the first and second side members; and
wherein the first guide rail is coupled with either the first and second top supports or the first and second bottom supports.

19. A modular equipment chassis system for an electronic equipment rack, the rack including a specified rack width dimension, and a specified rack depth dimension, the modular equipment chassis system comprising:
a first top support and a first bottom support, wherein the top and bottom supports include a plurality of corresponding mount locations;
a first substantially planar side member coupled to a first side of the first top support and to a first side of the first bottom support, wherein the first side member has a height corresponding to a specified rack height;
a second substantially planar side member coupled to a second side of the first top support and to a second side of the first bottom support, wherein the second side member has a height corresponding to the specified rack height;
a first guide rail coupled with at least one of the first top support and the first bottom support, wherein the first guide rail is configured to couple with at least one of the mount locations, and the first guide rail is further configured to receive and retain at least a side edge portion of a substantially planar first electronic appliance mount;
the substantially planar first electronic appliance mount, wherein the substantially planar first electronic appliance mount is coupled with the first guide rail and the substantially planar first electronic appliance mount is configured to be coupled with at least one enclosed electronic appliance using a non-conductive fastener;
a power supply module coupled with a portion of the modular equipment chassis system, wherein the power supply is configured to provide a first power signal; and
a power regulator coupled to the substantially planar first electronic appliance mount and configured to receive the first power signal from the power supply module and convert the first power signal to power signals that are different than the first power signal, and further configured to provide the different power signals to respective electronic appliances in the chassis.

20. A modular equipment chassis system for an electronic equipment rack, the rack including a specified rack width dimension, and a specified rack depth dimension, the system comprising:
a modular equipment chassis;
an electronic appliance mount coupled with the modular equipment chassis, wherein the electronic appliance mount is configured to be coupled with at least one enclosed electronic appliance using a non-conductive fastener;
a power supply module coupled with a portion of the modular equipment chassis, wherein the power supply is configured to provide a first power signal; and
a power regulator coupled to the electronic appliance mount and configured to receive the first power signal from the power supply module and convert the first power signal to different power signals than the first power signal, and wherein the power regulator is further configured to supply the different power signals to respective enclosed electronic appliances mounted to the electronic appliance mount.

21. The modular equipment chassis system of claim 20, wherein the modular equipment chassis includes:
a first top support and a first bottom support, wherein the top and bottom supports include a plurality of corresponding mount locations;
a first substantially planar side member coupled to a first side of the first top support and to a first side of the first bottom support, wherein the first side member has a height corresponding to a specified rack height;
a second substantially planar side member coupled to a second side of the first top support and to a second side of the first bottom support, wherein the second side member has a height corresponding to the specified rack height;
a first guide rail coupled with at least one of the first top support and the first bottom support, wherein the first guide rail is configured to couple with at least one of the mount locations; and
wherein the electronic appliance mount is coupled with the first guide rail.

22. The modular equipment chassis system of claim 21, wherein the first guide rail is further configured to receive and retain at least a side edge portion of the electronic appliance mount.
